(19) United States
(12) Patent Application Publication
(10) Pub. No.: US 2012/0206209 A1
(43) Pub. Date: Aug. 16, 2012

(54) System and Method for Reducing Temperature-and Process-Dependent Frequency Variation of a Crystal Oscillator Circuit

(76) Inventors: Kristopher Kevin Kaufman, Gilbert, AZ (US); John Wayne Simmons, Tamarac, FL (US)

(21) Appl. No.: 13/026,425

(22) Filed: Feb. 14, 2011

(51) Int. Cl. H03L 1/02

(52) U.S. Cl. 331/107 A; 331/176

(57) ABSTRACT

An oscillator may include a crystal resonator, an active element coupled in parallel with the crystal resonator and configured to produce at its output a waveform with an approximate 180-degree phase shift from its input, a voltage regulator a voltage regulator coupled to the active element, a sum of thresholds circuit coupled to the input of the voltage regulator, and a temperature-dependent current source coupled to the input of the voltage regulator. The voltage regulator may be configured to supply a supply voltage to the active element, the supply voltage a function of a reference voltage received at an input of the voltage regulator. The sum of thresholds circuit may be configured to generate the reference voltage such that the reference voltage is process-dependent. The temperature-dependent current source may be configured to generate a temperature-dependent current such that the reference voltage is temperature-dependent.

### TECHNICAL FIELD

The present disclosure relates generally to wireless communication and, more particularly, to reducing temperature- and process-dependent frequency variation of oscillator circuits.

### BACKGROUND

Wireless communications systems are used in a variety of telecommunications systems, television, radio and other media systems, data communication networks, and other systems to convey information between remote points using wireless transmitters and wireless receivers. A transmitter is an electronic device which, usually with the aid of an antenna, propagates an electromagnetic signal such as radio, television, or other telecommunications. Transmitters often include signal amplifiers which receive a radio-frequency or other signal, amplify the signal by a predetermined gain, and communicate the amplified signal. On the other hand, a receiver is an electronic device which, also usually with the aid of an antenna, receives and processes a wireless electromagnetic signal. In certain instances, a transmitter and receiver may be combined into a single device called a transceiver.

Transmitters, receivers, and transceivers often include components known as oscillators. An oscillator may serve many functions in a transmitter, receiver, and/or transceiver, including generating local oscillator signal (usually in a radio-frequency range) for upconverting baseband signals onto a radio-frequency (RF) carrier and performing modulation for transmission of signals, and/or for downconverting RF signals to baseband signals and performing demodulation of received signals.

To achieve desired functionality, such oscillators must often have designs that produce precise operating characteristics. For example, it is often critical that oscillator circuits operate independently of variations in manufacturing/fabrication process, and operate independently of the temperature of the oscillator circuit. However, in many existing oscillator circuits, variations in process and temperature may lead to undesired variations in the frequency of oscillation of an oscillator circuit.

### SUMMARY

In accordance with some embodiments of the present disclosure, an oscillator may include a crystal resonator, an active element coupled in parallel with the crystal resonator and configured to produce at its output a waveform with an approximate 180-degree phase shift from its input, a voltage regulator a voltage regulator coupled to the active element, a sum of thresholds circuit coupled to the input of the voltage regulator, and a temperature-dependent current source coupled to the input of the voltage regulator. The voltage regulator may be configured to supply a supply voltage to the active element, the supply voltage a function of a reference voltage received at an input of the voltage regulator. The sum of thresholds circuit may be configured to generate the reference voltage such that the reference voltage is process-dependent. The temperature-dependent current source may be configured to generate a temperature-dependent current such that the reference voltage is temperature-dependent.

Technical advantages of one or more embodiments of the present disclosure may include a mechanism to generate a process-dependent and temperature-dependent supply voltage to an active element of an oscillator circuit, thereby reducing or eliminating process and/or temperature dependence of performance of the active element.

It will be understood that the various embodiments of the present disclosure may include some, all, or none of the enumerated technical advantages. In addition, other technical advantages of the present disclosure may be readily apparent to one skilled in the art from the figures, description and claims included herein.

### BRIEF DESCRIPTION OF THE DRAWINGS

For a more complete understanding of the present disclosure and its features and advantages, reference is now made to the following description, taken in conjunction with the accompanying drawings, in which:

FIG. 1 illustrates a block diagram of an example wireless communication system, in accordance with certain embodiments of the present disclosure;

FIG. 2 illustrates a block diagram of selected components of an example transmitting and/or receiving element, in accordance with certain embodiments of the present disclosure;

FIG. 3 illustrates a block diagram of an example oscillator, in accordance with certain embodiments of the present disclosure; and

FIG. 4 illustrates a block diagram or certain embodiments of a programmable current source, in accordance with certain embodiments of the present disclosure.

### DETAILED DESCRIPTION

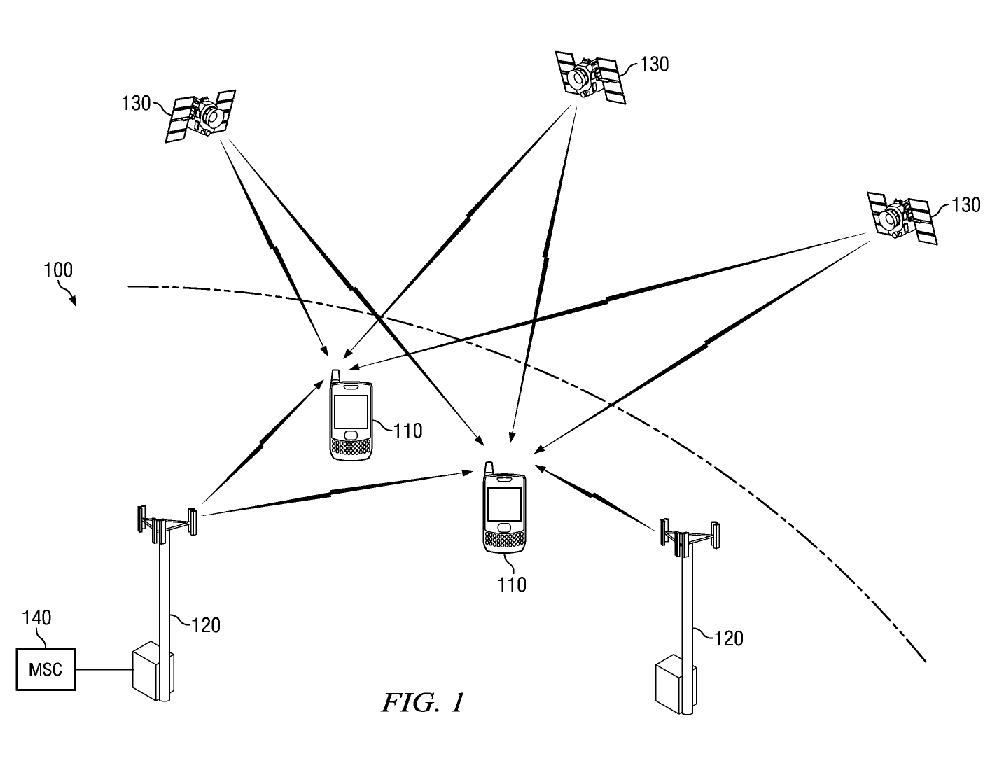

FIG. 1 illustrates a block diagram of an example wireless communication system 100, in accordance with certain embodiments of the present disclosure. For simplicity, only two terminals 110 and two base stations 120 are shown in FIG. 1. A terminal 110 may also be referred to as a remote station, a mobile station, an access terminal, user equipment (UE), a wireless communication device, a cellular phone, or some other terminology. A base station 120 may be a fixed station and may also be referred to as an access point, a Node B, or some other terminology. A mobile switching center (MSC) 140 may be coupled to the base stations 120 and may provide coordination and control for base stations 120.

A terminal 110 may or may not be capable of receiving signals from satellites 130. Satellites 130 may belong to a satellite positioning system such as the well-known Global Positioning System (GPS). Each GPS satellite may transmit a GPS signal encoded with information that allows GPS receivers on earth to measure the time of arrival of the GPS signal. Measurements for a sufficient number of GPS satellites may be used to accurately estimate a three-dimensional position of a GPS receiver. A terminal 110 may also be capable of receiving signals from other types of transmitting sources such as a Bluetooth transmitter, a Wireless Fidelity (Wi-Fi) transmitter, a wireless local area network (WLAN) transmitter, an IEEE 802.11 transmitter, and any other suitable transmitter.

In FIG. 1, each terminal 110 is shown as receiving signals from multiple transmitting sources simultaneously, where a transmitting source may be a base station 120 or a satellite 130. In certain embodiments, a terminal 110 may also be a transmitting source. In general, a terminal 110 may receive signals from zero, one, or multiple transmitting sources at any given moment.

System 100 may be a Code Division Multiple Access (CDMA) system, a Time Division Multiple Access (TDMA) system, or some other wireless communication system. A CDMA system may implement one or more CDMA standards such as IS-95, IS-2000 (also commonly known as “1x”), IS-856 (also commonly known as “1 xEV-DO”), Wideband-CDMA (W-CDMA), and so on. A TDMA system may implement one or more TDMA standards such as Global System for Mobile Communications (GSM). The W-CDMA standard is defined by a consortium known as 3GPP, and the IS-2000 and IS-856 standards are defined by a consortium known as 3GPP2.

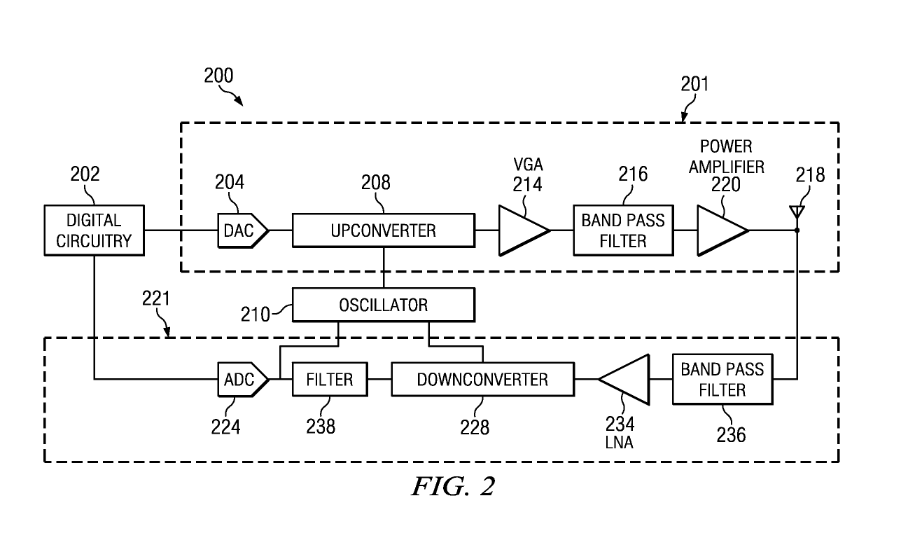

FIG. 2 illustrates a block diagram of selected components of an example transmitting and/or receiving element 200 (e.g., a terminal 110, a base station 120, or a satellite 130), in accordance with certain embodiments of the present disclosure. Element 200 may include a transmit path 201 and/or a receive path 221. Depending on the functionality of element 200, element 200 may be considered a transmitter, a receiver, or a transceiver.

As depicted in FIG. 2, element 200 may include digital circuitry 202. Digital circuitry 202 may include any system, device, or apparatus configured to process digital signals and information received via receive path 221, and/or configured to process signals and information for transmission via transmit path 201. Such digital circuitry 202 may include one or more microprocessors, digital signal processors, and/or other suitable devices.

Transmit path 201 may include a digital-to-analog converter (DAC) 204. DAC 204 may be configured to receive a digital signal from digital circuitry 202 and convert such digital signal into an analog signal. Such analog signal may then be passed to one or more other components of transmit path 201, including upconverter 208.

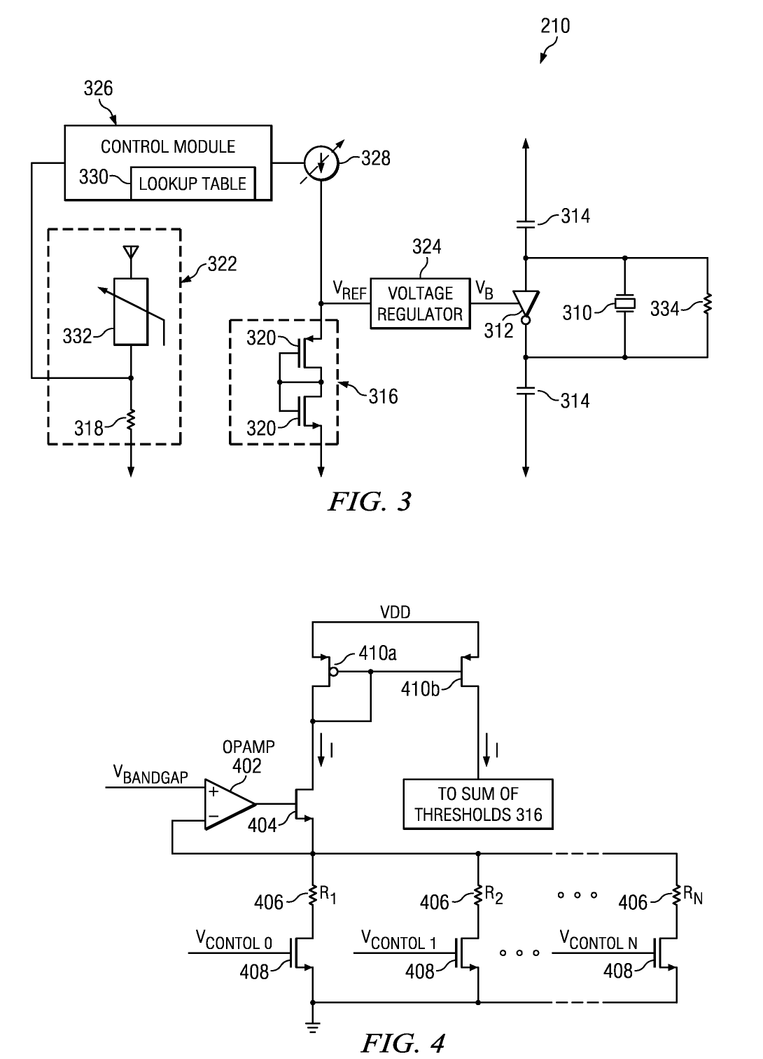

Upconverter 208 may be configured to frequency upconvert an analog signal received from DAC 204 to a wireless communication signal at a radio frequency based on an oscillator signal provided by oscillator 210. Oscillator 210 may be any suitable device, system, or apparatus configured to produce an analog waveform of a particular frequency for modulation or upconversion of an analog signal to a wireless communication signal, or for demodulation or downconversion of a wireless communication signal to an analog signal. In some embodiments, oscillator 210 may be a digitally-controlled crystal oscillator. Oscillator 210 may be described in greater detail below with reference to FIG. 3.

Transmit path 201 may include a variable-gain amplifier (VGA) 214 to amplify an upconverted signal for transmission, and a bandpass filter 216 configured to receive an amplified signal VGA 214 and pass signal components in the band of interest and remove out-of-band noise and undesired signals. The bandpass filtered signal may be received by power amplifier 220 where it is amplified for transmission via antenna 218. Antenna 218 may receive the amplified and transmit such signal (e.g., to one or more of a terminal 110, a base station 120, and/or a satellite 130).

Receive path 221 may include a bandpass filter 236 configured to receive a wireless communication signal (e.g., from a terminal 110, a base station 120, and/or a satellite 130) via antenna 218. Bandpass filter 236 may pass signal components in the band of interest and remove out-of-band noise and undesired signals. In addition, receive path 221 may include a low-noise amplifiers (LNA) 224 to amplify a signal received from bandpass filter 236.

Receive path 221 may also include a downconverter 228. Downconverter 228 may be configured to frequency downconvert a wireless communication signal received via antenna 218 and amplified by LNA 234 by an oscillator signal provided by oscillator 210 (e.g., downconvert to a baseband signal). Receive path 221 may further include a filter 238, which may be configured to filter a downconverted wireless communication signal in order to pass the signal components within a radio-frequency channel of interest and/or to remove noise and undesired signals that may be generated by the downconversion process. In addition, receive path 221 may include an analog-to-digital converter (ADC) 224 configured to receive an analog signal from filter 238 and convert such analog signal into a digital signal. Such digital signal may then be passed to digital circuitry 202 for processing.

FIG. 3 illustrates a block diagram of certain embodiments of oscillator 210, in accordance with certain embodiments of the present disclosure. As shown in FIG. 3, oscillator 210 may include a resonator 310 in parallel with an active element 312. Resonator 310 may include any piezoelectric material (e.g., a quartz crystal) with a mechanical resonance that may, in conjunction with other components of oscillator 210, create an electrical signal with a highly-precise frequency.

Active element 312 may include any system, device or apparatus configured to produce at its output a waveform with an approximate 180-degree phase shift from its input. In some embodiments, active element 312 may include an inverter, as depicted in FIG. 3. In such embodiments, if active element 312 receives a low voltage (e.g., logic 0) driven on its input, and may drive a high voltage (e.g., logic 1) on its output. Alternatively, if active element 312 receives a high voltage (e.g., logic 1) driven on its input, it may drive a low voltage (e.g., logic 0) on its output. Active element 312 may be implemented as a PMOS inverter, NMOS inverter, static CMOS inverter, saturated-load digital inverter, or any other suitable implementation. However, during operation, when implemented as an inverter, active element 312 may be biased in its linear region by means of feedback resistor 334, thus allowing it to operate as a high gain inverting amplifier. Resistor 334 may serve as a self-biasing resistor that provides a feedback path between the input and output of active element 312.

Each terminal of crystal resonator 310 may also be coupled to one or more capacitors 314. Although each terminal of crystal resonator 310 is depicted as being coupled to one capacitor 314, in some embodiments each terminal of crystal resonator 310 may be coupled to a “capacitor bank” of two or more capacitors. In such embodiments, all or a portion of such capacitors may be switched capacitors, therein allowing tuning of the effective capacitance of each capacitor bank and ultimately, tuning of the output frequency of oscillator 210. In many instances, any such capacitor banks of oscillator 210 may be substantially identical.

As shown in FIG. 3, oscillator 210 may also include voltage regulator 324. Programmable voltage regulator 324 may be coupled at its output to active element 312 and may include any system, device, or apparatus configured to automatically maintain a substantially constant supply bias voltage level (V_{B}) for active element 312, wherein such supply voltage is a function of a reference voltage V_{REF} received at the input of voltage regulator 324.

The input of voltage regulator 324 may be coupled as depicted in FIG. 3 to a sum of thresholds circuit 316 and a programmable current source 328. Sum of thresholds circuit 316 may include one or more transistors, diodes, or other active circuit elements arranged to generate, in the presence of an appropriate bias voltage, a voltage at V_{REF} approximately equal to the sum of the threshold voltages of such transistors, diodes, or other active circuit elements. For example, as shown in FIG. 3, sum of thresholds circuit 316 may include one or more transistors 320 arranged in series as shown in FIG. 3. In the depicted embodiments, one transistor 320 is coupled at its source or emitter to V_{REF}, while the other transistor 320 is coupled to ground at its source or emitter. The other active regions of the transistors 320 may be coupled to each other and the gates or bases of the transistors. Accordingly, in the presence of an adequate bias voltage, the voltage induced on V_{REF} will be approximately equal to the sum of the various threshold voltages (e.g., base-collector voltage, base-emitter voltage, gate-source voltage, gate-drain voltage, or other appropriate threshold voltage) of transistors 320. Although FIG. 3 depicts transistors 320 as complementary metal-oxide-semiconductor field-effect transistors, transistors 320 may include any other suitable type of transistor (e.g., bipolar junction transistor, junction-gate field effect transistor, insulated gate bipolar transistor, etc.). In addition, as mentioned above, other active circuit devices (e.g., diodes) may be used instead of transistors 320.

As depicted in FIG. 3, oscillator 210 may also include a programmable current source 328. Programmable current source 328 may include any electrical or electronic device configured to deliver or absorb electric current, wherein the amount of such electric current absorbed or delivered is dependent upon one or more received control signals received via a control input (e.g., control signals received from control module 326). Programmable current source 328 may be implemented in any suitable manner, including, without limitation, the embodiment depicted in FIG. 4, set forth below.

As shown in FIG. 3, oscillator 210 may additionally include a control module 326. Control module 326 may be coupled at its output to a control input of programmable current source 328, and may include any system, device, or apparatus configured to based at least on a signal received indicative of a temperature (e.g., a signal received from temperature sensor 322), generate control signals for controlling the current generated by programmable current source 328. Control module 326 may include a microprocessor, microcontroller, digital signal processor (DSP), application specific integrated circuit (ASIC), field programmable gate array (FPGA), erasable programmable read-only memory (EPROM), or any combination thereof.

As shown in FIG. 3, control module 326 may include a lookup table 330. Lookup table 330 may be implemented in a computer-readable medium (e.g., a memory), and may include a plurality of entries, each entry associating an input signal indicative of temperature to an output current control signal. Entries in lookup table 330 may be based at least on experimental data or measurements regarding the temperature-dependent variance of performance of one or more components of oscillator 210 (e.g., active element 312) and stored for use during operation. In some embodiments, control module 326 may not employ a lookup table, and may instead determine output current control signals based on calculation.

As depicted in FIG. 3, oscillator 210 may further include a temperature sensor 322 coupled at its output to an input of control module 326. Temperature sensor 322 may be any system, device, or apparatus configured to generate an electric or electronic signal (e.g., voltage or current) indicative of a temperature. For example, temperature sensor 322 may include a thermistor 332 in series with a resistor 318. Thermistor 332 may include a resistive device whose resistance varies significantly with temperature. Accordingly, thermistor 332 and resistor 318 may create a voltage divider whereby the voltage at a node common to thermistor 332 and resistor 318 may be a function of the temperature of thermistor 332. Accordingly, thermistor 332 may be placed proximate to components of oscillator 210 for which temperature measurement is desired (e.g., active element 312).

In oscillator circuits, performance of active elements (e.g., active element 312) is often dependent upon process variations of the oscillator circuits and variation in temperature during operation. Such process and temperature variations may cause changes in the performance of such active elements (e.g., gains, delays, etc.) that may lead to variance in the oscillation frequency of oscillator 210, or other undesirable effects.

The presence of sum of thresholds circuit 316 and programmable current source 328 may reduce such variations. For example, process variations present in components of sum of thresholds circuit 316 may be similar to process variations that may occur in components of active element 312. Accordingly, variation in reference voltage V_{REF} generated by sum of thresholds circuit 320 may vary across processes, thus allowing voltage regulator 324 to generate a process-dependent active element supply voltage V_{B}. Consequently, process-dependent variations of elements of active element 312 may be offset by the process-dependent supply voltage V_{B}.

In addition, temperature sensor 322 may be configured to detect a temperature of active element 312 or one or its components, or proximate to active element 312 or one or its components, and communicate a signal to control module 326 indicative of the detected temperature. Based on such signal, control module 326 may communicate a current control signal to programmable current source 328 such that current source 328 generates a temperature-dependent current. Changes in the temperature-dependent current may cause changes in the current reference V_{REF}, thus rendering V_{REF} dependent upon temperature in addition to process, thus allowing voltage regulator 324 to generate a temperature-dependent active element supply voltage V_{B}. Accordingly, temperature-dependent variations of elements of active element 312 may be offset by the temperature-dependent supply voltage V_{B}.

FIG. 4 illustrates a block diagram of certain embodiments of programmable current source 328, in accordance with certain embodiments of the present disclosure. As shown in FIG. 4, programmable current source 328 may include an operational amplifier 402, pass transistor 404, a plurality of resistors 406, selectively enabled transistors 408, and current mirror transistors 410.

Operational amplifier 402 may receive a voltage V_{bandgap} at its positive input terminal, and will thus produce an output of approximately V_{bandgap} on its negative input terminal. V_{bandgap} may be a process and temperature voltage generated by any appropriate components of programmable current source 328 or other component of element 200.

Each selectively enabled transistor 408 may be coupled between a corresponding resistor 406 and a ground voltage. Based on a control signal communicated by control module 326 (e.g., by reference to lookup table 330), one of selectively enabled transistors 408 may be enabled (thus coupling a terminal of its corresponding resistor 406 to ground) while all other selectively enabled transistors 408 may be disabled (thus leaving an open circuit on terminals of each of the resistors 406 corresponding to the disabled transistors 408). Accordingly, the current I passing through pass transistor 404 and current mirror transistor 410a may be approximately equal to the voltage V_{bandgap} divided by the resistor 406 corresponding to the enabled transistor 406. The current mirror formed by current mirror transistors 410a and 410b may cause the current I passing through transistor 410a to be mirrored by transistor 410b, and such current I may be output to sum of thresholds circuit 316 depicted in FIG. 3.

Modifications, additions, or omissions may be made to system 100 from the scope of the disclosure. The components of system 100 may be integrated or separated. Moreover, the operations of system 100 may be performed by more, fewer, or other components. As used in this document, “each” refers to each member of a set or each member of a subset of a set.

Although the present disclosure has been described with several embodiments, various changes and modifications may be suggested to one skilled in the art. It is intended that the present disclosure encompass such changes and modifications as fall within the scope of the appended claims.

What is claimed is:

1. A wireless communication element, comprising:
a receive path configured to receive a first wireless communication signal and convert the first wireless communication signal into a first digital signal based at least on an oscillator signal;
a transmit path configured to convert a second digital signal into a second wireless communication signal based at least on the oscillator signal and transmit the second wireless communication signal; and
an oscillator configured to output the oscillator signal to at least one of the receive path and the transmit path, the oscillator comprising:
a crystal resonator;
an active element coupled in parallel with the crystal resonator and configured to produce at its output a waveform with an approximate 180-degree phase shift from its input;
a voltage regulator coupled to the active element and configured to supply a supply voltage to the active element, the supply voltage a function of a reference voltage received at an input of the voltage regulator;
a sum of thresholds circuit coupled to the input of the voltage regulator and configured to generate the reference voltage such that the reference voltage is process-dependent; and
a temperature-dependent current source coupled to the input of the voltage regulator and configured to generate a temperature-dependent current such that the reference voltage is temperature-dependent.

2. A wireless communication element in accordance with claim 1, wherein the active element is an inverter.

3. A wireless communication element in accordance with claim 1, wherein the sum of thresholds circuit one or more active circuit elements arranged to generate, in the presence of an appropriate bias voltage, a voltage at the input of the voltage regulator approximately equal to the sum of the threshold voltages of the one or more active circuit elements.

4. A wireless communication element in accordance with claim 3, wherein the one or more active circuit elements include at least one of a transistor and a diode.

5. A wireless communication element in accordance with claim 1, the oscillator further including a control module coupled to communicate control signals to the temperature-dependent current source for controlling the current generated by the temperature-dependent current source.

6. A wireless communication element in accordance with claim 5, the oscillator further including a temperature sensor configured to:
detect a temperature; and
communicate a signal indicative of a temperature to the control module.

7. A wireless communication element in accordance with claim 6, wherein the temperature is measured proximate to the active element.

8. An oscillator, comprising:
a crystal resonator;
an active element coupled in parallel with the crystal resonator and configured to produce at its output a waveform with an approximate 180-degree phase shift from its input;
a voltage regulator coupled to the active element and configured to supply a supply voltage to the active element, the supply voltage a function of a reference voltage received at an input of the voltage regulator;
a sum of thresholds circuit coupled to the input of the voltage regulator and configured to generate the reference voltage such that the reference voltage is process-dependent; and
a temperature-dependent current source coupled to the input of the voltage regulator and configured to generate a temperature-dependent current such that the reference voltage is temperature-dependent.

9. An oscillator in accordance with claim 8, wherein the active element is an inverter.

10. An oscillator in accordance with claim 8, wherein the sum of thresholds circuit one or more active circuit elements arranged to generate, in the presence of an appropriate bias voltage, a voltage at the input of the voltage regulator approximately equal to the sum of the threshold voltages of the one or more active circuit elements.

11. An oscillator in accordance with claim 10, wherein the one or more active circuit elements include at least one of a transistor and a diode.

12. An oscillator in accordance with claim 8, further comprising a control module coupled to communicate control signals to the temperature-dependent current source for controlling the current generated by the temperature-dependent current source.

13. An oscillator in accordance with claim 12, further comprising a temperature sensor configured to:
detect a temperature; and
communicate a signal indicative of a temperature to the control module.

14. An oscillator in accordance with claim 13, wherein the temperature is measured proximate to the active element.

15. An method, comprising:
generating a process-dependent reference voltage;
generating a temperature-dependent current such that the reference voltage is temperature-dependent; and
regulating the reference voltage to produce a supply voltage to an active element of an oscillator circuit in parallel with a crystal resonator.

16. A method in accordance with claim 15, wherein the active element is an inverter.

17. An oscillator in accordance with claim 15, further comprising:
measuring a temperature proximate to the active element; and
generating the temperature-dependent current based at least on the measured temperature.
